(19) United States
(12) Patent Application Publication
(10) Pub. No.: US 2011/0148720 A1
(43) Pub. Date: Jun. 23, 2011

(54) NFC ANTENNA AIDED DESIGN SYSTEM AND DESIGN METHOD EMPLOYING THE SAME

(75) Inventors: YING YAO, Shenzhen City (CN); LEI WANG, Shenzhen City (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/771,279

(22) Filed: Apr. 30, 2010

(30) Foreign Application Priority Data
Dec. 21, 2009 (CN) 200910311916.8

(51) Int. Cl. G01R 29/08

(52) U.S. Cl. 343/703

(57) ABSTRACT

An exemplary embodiment of near field communication antenna aided design system includes a testing antenna, a standard antenna, and a network analyzer. The standard antenna is resonantly coupled with the testing antenna and includes two feed points. The network analyzer is electrically connected to the feed points and sends a test signal to the standard antenna. The standard antenna receives the test signal and is resonantly coupled with the testing antenna to generate a corresponding insertion loss reference curve. The network analyzer tests the insertion loss values on the insertion loss reference curve to obtain the resonant frequencies of the testing antenna. A design method employing the near field communication antenna aided design system is also provided.

### BACKGROUND

1. Technical Field

The disclosure generally relates to antenna design systems, and particularly, to a near field communication (NFC) antenna aided design system and design method employing the same.

2. Description of the Related Art

NFC antennas are widely used in various electronic devices for wireless communication. In the microwave system, parameter Sij of the NFC antenna illustrates a relationship between incident wave and reflected wave. In detail, both i and j represent different ports, the port i represents input port and is used to input power, and port j represents output port and is used to output power. In the two-port network, if port 1 is defined as input port (source port), and port 2 is defined as output port (destination port), then S11 represents return loss, that is, how much energy is reflected back to the port 1, and S21 represents insertion loss (namely, the power attenuation from port 1 to port 2), that is, how much energy is transferred to port 2.

Popularly used NFC antenna aided design methods include connecting a vector network analyzer to signal inception points of an antenna via a cable; adjusting the parameters S11 (return loss) curve of the antenna to obtain the size parameters of the antenna; and obtaining the resonant frequency of the antenna. However, the obtained return loss of the NFC antenna using this method is generally between 0-4 dB, and the waveform of the parameters S11 curve is relatively flat.

Therefore, there is room for improvement within the art.

### BRIEF DESCRIPTION OF THE DRAWINGS

Many aspects of an NFC antenna aided design system and design method employing the same can be better understood with reference to the following drawings. The components in the drawings are not necessarily drawn to scale, the emphasis instead being placed upon clearly illustrating the principles of the exemplary NFC antenna aided design system and design method employing the same. Moreover, in the drawings, like reference numerals designate corresponding parts throughout the several views. Wherever possible, the same reference numbers are used throughout the drawings to refer to the same or like elements of an embodiment.

FIG. 1 is a block diagram of an NFC antenna aided design system, according to an exemplary embodiment.

FIG. 2 is a schematic view of a testing antenna in the NFC antenna aided design system shown in FIG. 1, having exemplary size information.

FIG. 3 is a flowchart illustrating a method of designing an NFC antenna, according to an exemplary embodiment of the disclosure.

FIG. 4 is a schematic illustration of a relationship between frequency (X-axis) and corresponding insertion loss (Y-axis), showing generation of an S21 (insertion loss) reference curve by a standard antenna resonantly coupled with the testing antenna shown in FIG. 2.

### DETAILED DESCRIPTION

The operating frequency of an NFC antenna is about 13.56 MHz, and, with no electromagnetic activity near the frequency domain of the operating frequency 13.56 MHz, the NFC antenna can be tested and designed via resonantly coupling between different antennas.

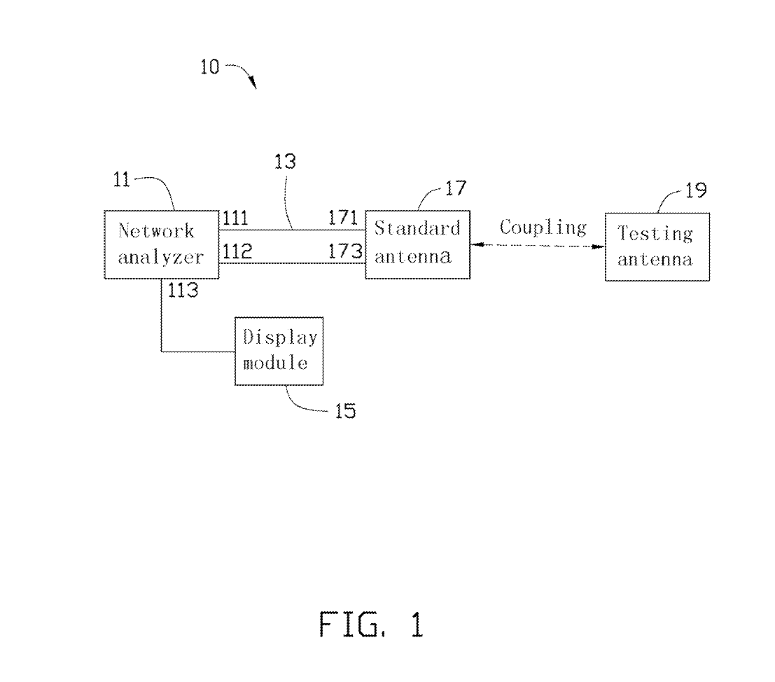

FIG. 1 is a block diagram of an NFC antenna aided design system 10 according to an exemplary embodiment. The NFC antenna aided design system 10 includes a network analyzer 11, two cables 13, a display module 15, a standard antenna 17, and a testing antenna 19. The display module 15, the network analyzer 11, the standard antenna 17 are electrically connected in sequence, among them, the network analyzer 11 is connected to the standard antenna 17 through the cables 13. The standard antenna 17 is resonantly coupled with the testing antenna 19 as described below, resulting in generation of a resonantly coupled signal.

The network analyzer 11 can be a vector network analyzer or a scalar network analyzer, used to test the S21 parameters (insertion losses) of the standard antenna 17 to establish a corresponding S21 reference curve. The network analyzer 11 includes two test ports 111 and 112, and a data port 113. The two test ports 111 and 112 are respectively connected to the two cables 13 to transmit a test signal and receive the resonantly coupled signal from the standard antenna 17. The data port 113 is electrically connected to the display module 15 by, for example, cable, to transmit the S21 parameters from the network analyzer 11 to the display module 15.

The display module 15, as an information output interface, provides S21 parameters from the network analyzer 11 for viewing. The display module 15 can be a computer or computer-enabled electronic device. The standard antenna 17 is a designed NFC antenna with resonant frequency of 13.56 MHz. The standard antenna 17 includes two feed points 171 and 173, respectively electrically connected to the cables 13.

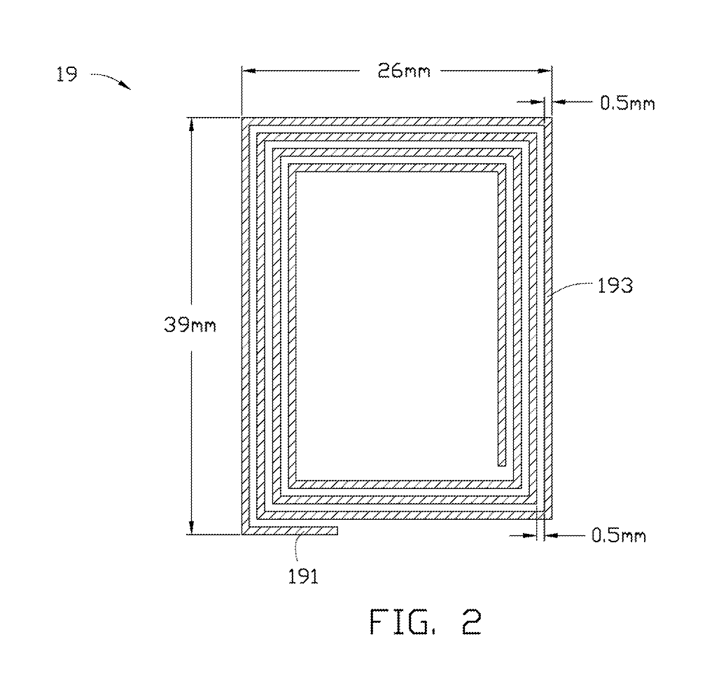

Further referring to FIG. 2, in this exemplary embodiment, the testing antenna 19 includes a plurality of coils 191, and may be formed by bending the coils 191. The shaped and bent coils 191 form a plurality of rectangular radiating sections 193, which have increasing side lengths from the center of the testing antenna 19, outwards. The testing antenna 19 is located on (positioned in contact with) and resonantly coupled with the standard antenna 17, thereby generating resonance. The network analyzer 11 tests the S21 parameters of the standard antenna 17 and then generates corresponding resonant frequencies. The display module 15 displays the S21 reference curve to illustrate the relationship between the resonant frequencies and corresponding insertion losses. Thus, the resonant frequencies of the testing antenna 19 corresponding to the standard 17 are obtained by adjusting the shape and size of the testing antenna 19. In this embodiment of the disclosure, resonant frequencies of the testing antenna 19 of about 13.56±1.5 MHz, fully satisfy design requirements as desired.

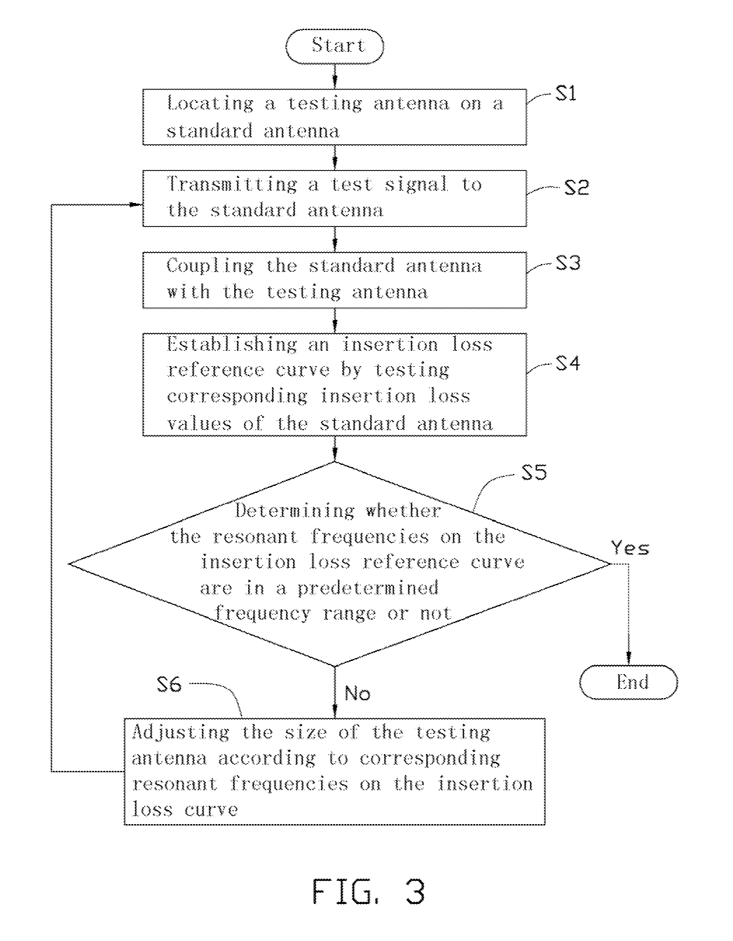

Further referring to FIG. 3, a method of designing a NFC antenna according to an exemplary embodiment of the disclosure, including at least the following steps, is depicted.

In step S1, a standard antenna 17 and a testing antenna 19 are provided, and the testing antenna 19 is located on the standard antenna 17. The standard antenna 17 is a NFC antenna.

In step S2, a test signal is transmitted to the standard antenna 17. In detail, the network analyzer 11 transmits the testing signal to the standard antenna 17 through the test port 111 or the test port 112.

In step S3, the standard antenna 17 receives the test signal and is resonantly coupled with the testing antenna 19 to obtain resonant frequencies.

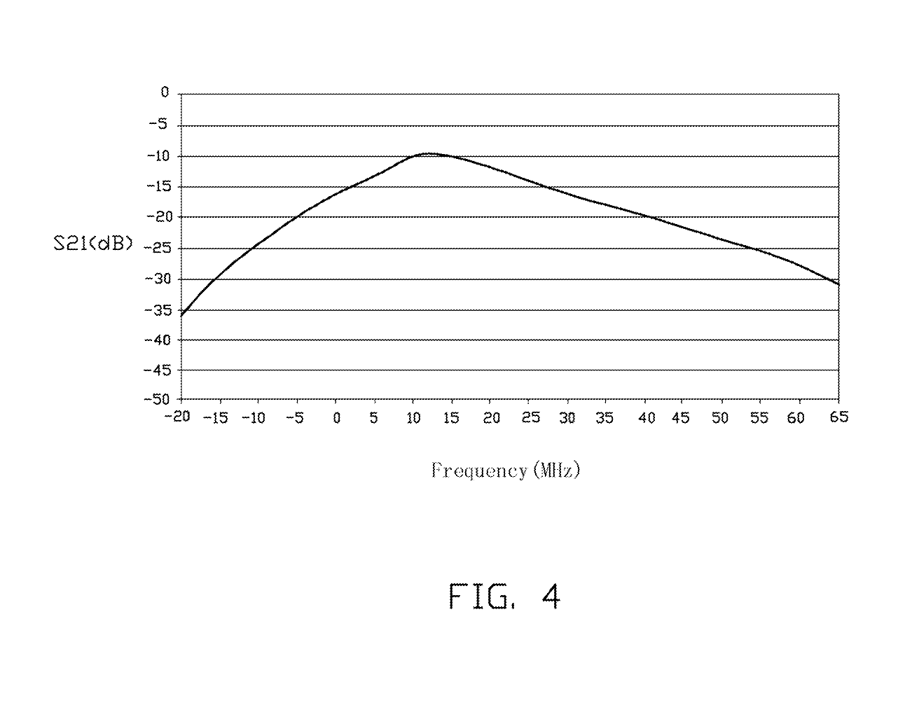

In step S4, a S21 (insertion loss) reference curve (shown in FIG. 4) is established by testing the S21 parameters of the standard antenna 17. In detail, the test port 112 or the test port 111 of the network analyzer 11 receives and tests the S21 parameters to generate the S21 reference curve, and the S21 reference curve is displayed on the display module 15.

In step S5, the resonant frequencies on the S21 reference curve are obtained to determine whether the testing antenna 19 meets the design requirements or not. In particular, if the resonant frequencies on the S21 reference curve are within a predetermined range of 13.56±1.5 MHz, the testing antenna 19 meets the requirements for the NFC antenna and the process is complete. If not, step S6 is implemented.

In step S6, the shape and the size of the testing antenna 19 are adjusted to comply with design requirements. For example, the length and/or the width of the coils 191 are adjusted, and/or the interval distance between any two adjacent radiating sections 193, then step S2 is repeated.

One set of design parameters of the testing antenna 19 determined according to the method may be: four radiating sections 193; 0.5 millimeter (mm) between the sides of any two adjacent radiating sections 193 and 0.5 millimeter (mm) width of the coils 191; the long sides of the outermost radiating section 193 are 39 mm long, and the short sides of the outermost radiating section 193 are 26 mm long.

In summary, in the NFC antenna aided design system 10 and design method employing the same of the exemplary embodiment, the network analyzer 11 generates a S21 (insertion loss) reference curve according to the resonant frequencies, and the resonant frequencies and the insertion losses are displayed on the S21 reference curve. Thus, the NFC antenna design parameters are obtained according to the resonant frequencies.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A near field communication aided design method, the method comprising:
providing a standard antenna and a testing antenna and locating the testing antenna on the standard antenna;
transmitting a test signal to the standard antenna;
resonantly coupling the standard antenna with the testing antenna;
establishing an insertion loss reference curve by testing corresponding insertion loss values of the test signal of the standard antenna; and
adjusting the size of the testing antenna according to corresponding resonant frequencies on the insertion loss reference curve.

2. The near field communication aided design method as claimed in claim 1, further comprising determining whether the resonant frequencies on the insertion loss reference curve are in a predetermined frequency range or not, wherein if the resonant frequencies on the insertion loss reference curve are in the predetermined frequency range, the testing antenna is acceptable for use as a near field communication antenna.

3. The near field communication aided design method as claimed in claim 2, wherein if the resonant frequencies on the insertion loss reference curve are beyond the predetermined frequency range, the size of the testing antenna is adjusted to cause the resonant frequencies to be within the predetermined frequency range.

4. The near field communication aided design method as claimed in claim 3, wherein the testing antenna comprises a plurality of coils, the testing antenna may be formed by bending the coils, and the bent coils form a plurality of radiating sections.

5. The near field communication aided design method as claimed in claim 4, wherein size adjustment of the testing antenna comprises adjusting the length and/or width of the coils of the testing antenna, and/or adjusting the interval distance between two adjacent coils.

6. The near field communication aided design method as claimed in claim 1, wherein the insertion loss reference curve illustrates a relationship between frequencies and corresponding insertion losses to obtain the resonant frequencies.

7. A near field communication aided design system, the system comprising:
a testing antenna;
a standard antenna resonantly coupled with the testing antenna, the standard antenna comprising two feed points; and
a network analyzer electrically connected to the feed points, wherein the network analyzer sends a test signal to the standard antenna, the standard antenna receives the test signal and resonantly coupled with the testing antenna to generate a corresponding insertion loss reference curve, and the network analyzer tests the insertion loss values on the insertion loss reference curve to obtain the resonant frequencies of the testing antenna.

8. The near field communication aided design system as claimed in claim 7, wherein the standard antenna is a near field communication antenna.

9. The near field communication aided design system as claimed in claim 7, further comprising a display module, wherein the display module is electrically connected to the network analyzer and displays the insertion loss reference curve.

10. The near field communication aided design system as claimed in claim 7, wherein the testing antenna comprises a plurality of coils, the testing antenna may be formed by bending the coils, and the bent coils form a plurality of radiating sections.

11. The near field communication aided design system as claimed in claim 10, wherein size adjustment of the testing antenna comprises adjusting the length and/or width of the coils of the testing antenna, and/or adjusting the interval distance between two adjacent coils.

12. The near field communication aided design system as claimed in claim 7, wherein the insertion loss reference curve illustrates a relationship between frequencies and corresponding insertion losses to obtain the resonant frequencies.
